(19) United States
(12) Patent Application Publication
(10) Pub. No.: US 2017/0006701 A1
(43) Pub. Date: Jan. 5, 2017

(54) BIODEGRADABLE PRINTED CIRCUIT BOARDS AND METHODS FOR MAKING THE PRINTED CIRCUIT BOARDS

(71) Applicant: EMPIRE TECHNOLOGY DEVELOPMENT LLC, Wilmington, DE (US)

(72) Inventor: Vincenzo CASASANTA, III, Woodinville, WA (US)

(73) Assignee: EMPIRE TECHNOLOGY DEVELOPMENT LLC, Wilmington, DE (US)

(21) Appl. No.: 15/125,573

(22) PCT Filed: Mar. 11, 2014
(86) PCT No.: PCT/US14/23192

§ 371 Date: Sep. 12, 2016

(51) Int. Cl. H05K 1/03; H05K 1/11; H05K 1/18; H05K 3/40; H05K 3/12; C08J 5/04; B32B 5/12; B32B 27/08; B32B 27/18; B32B 27/22; B32B 27/36; C08J 5/00; H05K 1/09; H05K 3/00

(52) U.S. Cl. CPC H05K 1/0366; H05K 1/0393; H05K 1/095; H05K 1/115; H05K 1/181; H05K 3/4038; H05K 3/125; H05K 3/0011; B32B 5/12; B32B 27/08; B32B 27/18; B32B 27/22; B32B 27/36; C08J 5/005; C08J 5/041; H05K 2203/178; B32B 2307/7163; B32B 2260/046; B32B 2307/202; B32B 2457/08; C08J 2367/04

(57) ABSTRACT

Biodegradable printed circuit boards, or PCBs, may be produced from substrate sheets that include at least one biodegradable polymer. In addition, the electrical traces used on the PCBs, may also include a biodegradable polymer incorporated with an electrically conductive material. The PCBs may be composted to degrade the PCBs, and the

### BACKGROUND

A printed circuit board, or PCB, is typically a thin flat board made of fiberglass or other similar non-conductive material, onto which electrically conductive wires or traces are printed or etched. Electronic components, such as integrated circuits, resistors, capacitors, diodes, electronic filters, microcontrollers, relays, and so on, may be mounted on the board, and the traces connect the components together to form a working circuit or assembly. A PCB may have conductors on one side or both sides, and may be multi-layered, having many layers of conductors, each separated by insulating layers. While most PCBs are flat and rigid, flexible substrates may also be used. Some examples of PCBs include computer motherboards, memory modules, and network interface cards.

Items with logic, memory, and PCBs enter the waste stream continuously. In many countries, a two or three-year-old cell phone, portable music player, or gaming console is considered out of date and may be disposed of Thus, an unintended consequence of the information technology revolution is new and potentially toxic waste. Estimates suggest that 100 million computers are discarded worldwide every year. In the United States this amounts to about two million tons of computer-related waste per year and climbing. The European Union has identified waste electrical and electronic equipment (WEEE) as the fastest growing waste stream, amounting to about 5% of the municipal solid waste (MSW) and growing at three times the rate of the total MSW stream.

In many places, PCBs are incinerated to burn away the epoxy or fiberglass substrates in order to reclaim any copper, nickel, tin or lead that are on the boards. Fumes from the incineration can be toxic, and inhalation can potentially cause health problems. Many PCBs, on the other hand, end up in landfills, may result in toxic run-off, and may take hundreds of years to decompose, if not longer.

Therefore, there remains a need for reducing potential hazards presented by PCB disposal and reclamation.

### SUMMARY

Printed circuit boards, or PCBs, may be produced from substrate sheets that include at least one biodegradable polymer. In addition, the electrical traces used on the PCBs, may also include a biodegradable polymer incorporated with an electrically conductive material, such as a metal. Once the PCB reaches its end of life, it may be composted to degrade wherein essentially only the electrically conductive material will remain, and the electrically conductive material may be reclaimed for re-use.

In an embodiment, a biodegradable printed circuit board may include at least one substrate sheet and one or more electrical conduction traces disposed on the at least one substrate sheet. The substrate sheet may include a composite of at least a first polymer and fiber reinforcements, wherein the first polymer may be biodegradable

In an embodiment, a flexible substrate sheet for supporting electronic components may include a composite of at least a first polymer and fiber reinforcements, wherein the first polymer is biodegradable.

In an embodiment, a method for making a biodegradable printed circuit board may include forming a composite of a first polymer and fiber reinforcements, wherein the first polymer is biodegradable, forming the composite into a substrate sheet, and depositing one or more electrical conduction traces on the substrate sheet.

In an embodiment, a method for disposal of at least one biodegradable printed circuit board includes removing electronic components from a substrate sheet of the printed circuit board, wherein the substrate sheet includes a biodegradable polymer and one or more electrical conduction traces disposed on the substrate sheet, and the electrical conduction traces include an electrically conductive material. The method also includes composting the substrate sheet to degrade the biodegradable polymer into a compost containing the electrically conductive material, and recovering the electrically conductive material from the compost.

### BRIEF DESCRIPTION OF THE FIGURES

FIG. 1 depicts a representation of a biodegradable printed circuit board and method steps for producing a biodegradable printed circuit board according to an embodiment.

FIG. 2 depicts a representation of a method for disposal of biodegradable printed circuit boards according to an embodiment.

### DETAILED DESCRIPTION

Electronic substrate materials, such as those used in PCBs, may include many layers of substrate that are formed from a biodegradable polymer with whisker or fiber reinforcements. For simplification, the term “fiber” is used below to include both fibers and whiskers. The fibers may be directionally oriented in each layer to achieve desired mechanical and/or thermal properties for the end use of the substrate. The substrate layers may each include electrical traces that are printed on the surfaces of the layers or extend through the layers. The material that forms the traces may also include a biodegradable polymer. As such, a resulting substrate may be formed as a multi-layer electronic circuit with traces that run in three dimensions through each of the layers. At the end of the useful life of the substrate, the substrate may be composted so that it degrades and essentially leaves behind only the electrically conductive material of the traces, which may then be reclaimed for re-use.

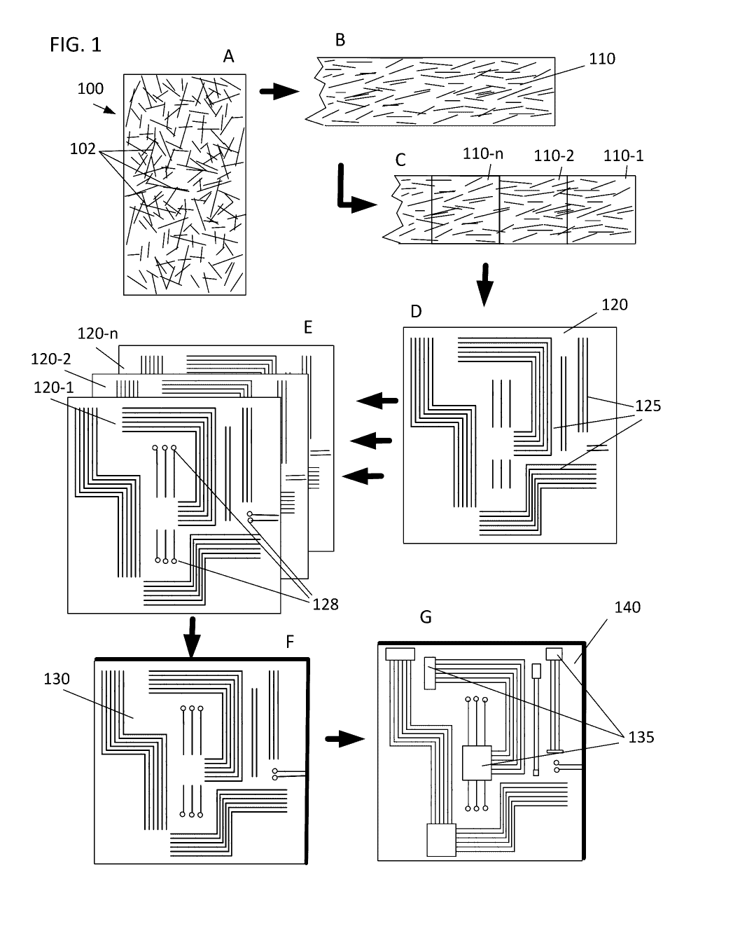

In an embodiment, a flexible substrate sheet for supporting electronic components may include a composite of a first polymer and fiber reinforcements, wherein the first polymer is biodegradable. FIG. 1A depicts a representation of a composite material 100 having a plurality of fiber reinforcements 102 embedded therein. The fibers may be nano fibers, micro fibers, or both, and the composite material 100 may contain about 1 wt % to about 75 wt % fibers.

The composite material 100 may include at least one biodegradable polymer. Some examples of biodegradable polymers may include, but are not limited to starch, polyhydroxy alkanoates, polyvinyl alcohol, polylactic acid, poly(3-hydroxypropanoic acid), or any combination thereof.

In an embodiment, the biodegradable polymer may be polylactic acid, a random copolymer of polylactic acid and at least one additional monomer, a block copolymer of polylactic acid and at least one additional monomer, a graft copolymer of polylactic acid and at least one additional monomer, or any combination thereof. Some examples of additional monomers may include, but are not limited to glycolic acid, poly(ethylene glycol), poly(ethylene oxide), poly(propylene oxide), (R)-beta-butyrolactone, delta-valerolactone, epsilon-caprolactone, 1,5-dioxepan-2-one, trimethylene carbonate, alkylthiophene, and N-isopropylacrylamide.

In an embodiment, a flexible substrate sheet for supporting electronic components may include a composite of polylactic acid and fiber reinforcements. Polylactic acid resins may be formed by direct condensation of lactic acid, or in combination with the cyclic di-ester of lactic acid-lactide. Any references to polylactic acid herein are meant to include either poly (D-lactic acid) compositions, poly (L-lactic acid) compositions, or poly (D,L-lactic acid) compositions.

In an embodiment, in addition to the first biodegradable polymer, the composite may also include an additional polymer that is different from the first biodegradable polymer. The additional polymer may be selected from polyolefins, polyesters, polyamides, polyimides, polyketones, polyisocyanates, polysulphones, styrenic plastics, phenolic resins, amide resins, urea resins, melamine resins, polyester resins, epoxidic resins, polycarbonates, polyvinylpyrrolidones, epoxy resins, polyacrylates, rubbers and gums, polyurethanes, silicones, aramids, polybutadiene, polyisoprenes, polyacrylonitriles, polyvinyl difluoride, polyvinyl acetate, polyvinyl alcohol, ethylene vinyl alcohol, vinyl polychloride, polyvinyldiene chloride, biomass derivatives, proteins, polysaccharides, lipids, biopolyesters, or any combination thereof.

The fiber reinforcements 102 that are included in the composite 100 may be at least one of cellulose, cellulosic fibers, flax, alumina, silicon carbide, aluminum nitride, silicon nitride, silicon dioxide, aluminosilicates, inorganic metal silicate glass fibers, borosilicates, or any combination thereof. In one embodiment, for example, the composite may include polylactic acid as the biodegradable polymer, and inorganic fibers as the fiber reinforcements. Alumina, silicon carbide, aluminum nitride, silicon nitride, and silicon dioxide have very low coefficients of thermal expansion (about 3 ppm/° C. to about 9 ppm/° C.). A substrate that includes fibers of alumina, silicon carbide, aluminum nitride, silicon nitride, and silicon dioxide may therefore also have low coefficient of thermal expansion.

The fibers may have a cross-sectional dimension of about 10 nanometers to about 100 microns and a length of about 100 nanometers to about 1000 microns.

In embodiments, the fibers may have a cross-sectional dimension of about 10 nm, about 50 nm, about 100 nm, about 200 nm, about 300 nm, about 400 nm, about 500 nm, about 600 nm, about 700 nm, about 800 nm, about 900 nm, about 1 μm, about 2 μm, about 3 μm, about 4 μm, about 5 μm, about 6 μm, about 7 μm, about 8 μm, about 9 μm, about 10 μm, about 20 μm, about 30 μm, about 40 μm, about 50 μm, about 60 μm, about 70 μm, about 80 μm, about 90 μm, about 100 μm, or any value between any of the listed values, or range extending between any two of the listed values.

In embodiments, the fibers may have a length of about 100 nm, about 200 nm, about 300 nm, about 400 nm, about 500 nm, about 600 nm, about 700 nm, about 800 nm, about 900 nm, about 1 μm, about 2 μm, about 3 μm, about 4 μm, about 5 μm, about 6 μm, about 7 μm, about 8 μm, about 9 μm, about 10 μm, about 20 μm, about 30 μm, about 40 μm nm, about 50 μm, about 60 μm, about 70 μm, about 80 μm, about 90 μm, about 100 μm, about 200 μm, about 300 μm, about 400 μm, about 500 μm, about 600 μm, about 700 μm, about 800 μm, about 900 μm, about 1000 μm, or any value between any of the listed values, or range extending between any two of the listed values.

Combinations of various fibers and polymers, as well as amounts of each of the components may be varied to alter various mechanical, thermal, electrical, and optical properties of the composite and substrate sheets that may be formed from the composite. Some examples of the properties that may be varied include elastic modulus, yield stress, ultimate tensile strength, coefficient of thermal expansion, thermal conductivity, impact strength, heat capacity, density, flammability, electrical resistance, dielectric constant, dielectric strength, electric permittivity, magnetic permeability, optical transmissivity, and index of refraction.

In various embodiments, the composite may also include at least one additive selected from plasticizers, emulsifiers, anti-flocculants, processing aids, antistatics, light absorbers, antioxidants, cross-linkers, flame retardants, and antibacterials.

A composite of selected ones of the above-listed components may be formed into sheets for use as a substrate material. The composite may be rolled, pressed, extruded, or otherwise formed into sheets. A substrate sheet 110 may have generally any thickness, such as a thickness of about 50 μm to about 3 mm. In various embodiments, a substrate sheet may have a thickness of about 50 μm, about 75 μm, about 100 μm, about 200 μm, about 300 μm, about 400 μm, about 500 μm, about 600 μm, about 700 μm, about 800 μm, about 900 μm, about 1 mm, about 1.2 mm, about 1.4 mm, about 1.6 mm, about 1.8 mm, about 2 mm, about 2.2 mm, about 2.4 mm, about 2.6 mm, about 2.8 mm, about 3 mm, or any thickness value between any of the listed values.

In an embodiment, as shown in FIG. 1B, the fibers 102 may be longitudinally oriented in a substrate sheet 110. The fibers 102 may be longitudinally oriented by extruding the composite 100 to form a sheet 110, wherein the fibers may become longitudinally oriented in the direction of the extrusion. After extrusion, the composite may be pressed and calandered to form a sheet 110 with oriented fibers 102. As depicted in FIG. 1C, the sheet 110 may be cut into smaller sections 110-1, 110-2 . . . 110-n, that may be sized as needed. In an embodiment, varying the degree or extent of longitudinal orientation of the fibers may provide an alteration of at least one of elastic modulus, yield stress, ultimate tensile strength, coefficient of thermal expansion, thermal conductivity, impact strength, heat capacity, and density of the composite, and any substrates produced from the composite.

Depending on the composition of the substrate sheets, the substrate sheets may be flexible. As represented in FIG. 1D, a flexible substrate sheet for supporting electronic components may include one or more electrical conduction traces 125 disposed on the substrate sheet 120. The electrical conduction traces 125 may include a conductive material, such as metal, and beads of a biodegradable polymer. In an embodiment, the beads may be beads of starch, polyhydroxy alkanoates, polyvinyl alcohol, polylactic acid, poly(3-hydroxypropanoic acid), or any combination thereof. The beads may be microbeads, and may have a diameter of about 10 nm to about 30 μm. In embodiments, for example, the microbeads may have a diameter of about 10 nm, about 30 nm, about 60 nm, about 100 nm, about 300 nm, about 600 nm, about 1 μm, about 3 μm, about 6 μm, about 10 μm, about 12 μm, about 14 μm, about 16 μm, about 18 μm, about 20 μm, about 22 μm, about 24 μm, about 26 μm, about 28 μm, about 30 μm, or any value between any of the listed values or any range of sizes extending between any two of the listed values.

The conductive material in the traces may be a conductive metal such as, but not limited to, silver, aluminum, copper, zinc, nickel, gold, platinum, palladium, or any combination thereof. In an alternate embodiment, the conductive material may be a conducting polymer such as, but not limited to polyacetylenes, polyphenylene vinylene, polypyrrole, polythiophene, polyaniline, polyphenylene sulfide, polyfluorenes, polypyrenes, polyvinylcarbazoles, polyazulenes, polynaphthalenes, polyindoles, or any combination thereof.

At least about 50% of the volume of the electrical conduction traces may be metal. In embodiments, the percentage by volume of metal in the traces may be, for example, about 50%, about 55%, about 60%, about 65%, about 70%, about 75%, about 80%, about 85%, about 90%, about 95%, about 100%, or any amount between any of the listed values.

In one embodiment, the electrical conduction traces may include silver as the conducting material and beads of polylactic acid as the biodegradable polymer.

The electrical conduction traces 125 may be formed by depositing a conducting paste, containing the conducting material and beads of a biodegradable polymer, onto the surface of the substrate sheet. The paste may be deposited by various methods, such as at least one of inkjet printing, screen printing, stencil printing, 3D printing, needle dispensing, contact printing, stamp printing, gravure printing, or any combination thereof. The paste may include at least one solvent for liquification, and upon depositing of the past onto the substrate, the solvent may be evaporated to leave a dry stable film of conductive material as an electrical trace on the substrate.

A substrate sheet may also be configured to receive electronic components thereon, with the electronic components disposed in contact with the electrical conduction traces 125. The electronic components may be affixed to the substrate with a conductive adhesive. For example, a silver-loaded adhesive may provide some flexibility and may allow for slight movement or deformation of the attached components. One example of a substrate sheet with electronic components may be as represented in FIG. 1G, wherein the material referenced by number 140 may represent a single substrate sheet, such as sheet 120, with traces 125 and electronic components 135 mounted thereon in contact with the electrical conduction traces. The electronic components 135 may include, but are not limited to, a microprocessor, a diode, a microcontroller, an integrated circuit, a capacitor, a resistor, a transformer, an inductor, a coil, a logic device, a connector pin, a battery, an antennae, a light emitting diode, a switch, a sensor, a system-in-package.

In one embodiment, a substrate sheet 140 with electronic components 135 mounted thereon, as represented in FIG. 1G, may be a biodegradable printed circuit board (PCB). In an embodiment, a plurality of sheets 120, as represented by sheets 120-1, 120-2, 120-n in FIG. 1E, may be stacked and laminated together to form a laminated substrate 130 as represented in FIG. 1F. For example, five layers/sheets of about 50 μm thickness may be laminated together to form a flexible electronics substrate with a thickness of about 250 microns. In embodiments, a printed circuit board may include one sheet, two laminated sheets, three laminated sheets, four laminated sheets, five laminated sheets, six laminated sheets, seven laminated sheets, eight laminated sheets, or any number of laminated sheets as may be needed for a particular use. Sheets 120-1, 120-2, 120-n may be configured, with respect to one another, so that the longitudinal direction of the reinforcement fibers 102 in all of the sheets is the same. Alternatively, the longitudinal direction of the reinforcement fibers 102 in at least one substrate sheet may be oriented in a direction different from the longitudinal orientation of the fiber reinforcements in at least one other of the substrate sheets. In an embodiment, the longitudinal orientation of the fibers in each sheet may be different from the longitudinal orientation of the fibers in any adjacent sheet.

As represented in FIG. 1E, the general longitudinal direction of the fiber reinforcements in the top and bottom sheets are oriented transverse to the general direction of the fibers in the middle sheet. In other embodiments, the general longitudinal orientation of the fibers in any of the sheets may be disposed at any angular orientation with respect to the general longitudinal orientation of fibers in at least one other sheet. In various embodiments, the general angular orientation between the fibers in different ones of the sheets may be about 0°, about 5°, about 10°, about 15°, about 20°, about 25°, about 30°, about 35°, about 40°, about 45°, about 50°, about 55°, about 60°, about 65°, about 70°, about 75°, about 80°, about 85°, about 90°, or any angle between any of the listed values.

To provide electrical communication between the sheets 120-1, 120-2, 120-n, holes or vias 128, as shown in FIG. 1E, may be drilled through the sheets. The holes may be filled with a conductive paste, such as the paste used to form the traces 125, to conduct electrical current from conductive traces on one sheet to conductive traces on another sheet.

In an embodiment, after any traces are deposited and vias are drilled, one corresponding sheet may be laminated onto another sheet, and conductor paste may be provided into the vias. The process may be continued such that several layers of substrate sheets having a 2-D (x, y plane) pattern of traces on the sheets, may be interconnected across layers (z-direction) by the drilled and filled vias. Once the final stack up is finished the laminate may be heated under slight pressure to join all the layers and fix the conductor traces

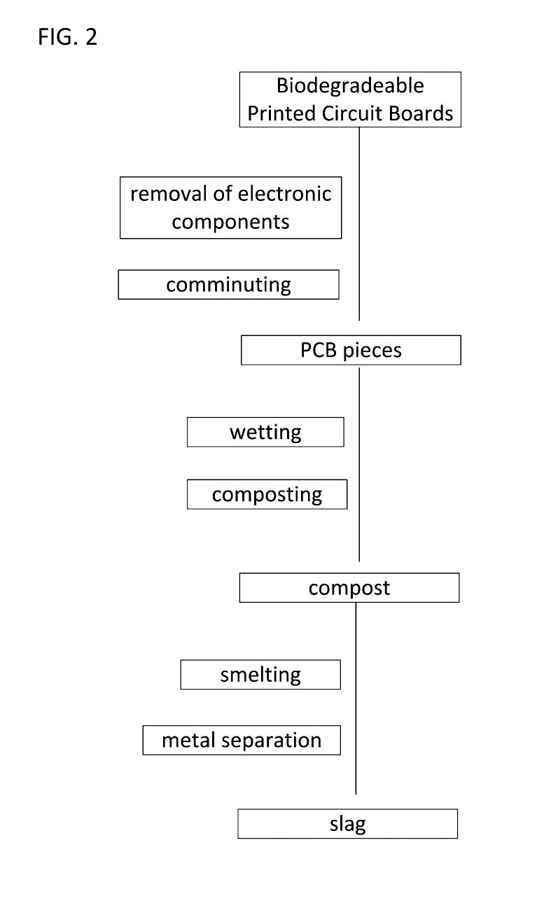

A substrate, such as substrate 140, produced in accordance with the details as discussed above, may have a useful life of multiple years. The substrate may be a printed circuit board including a biodegradable polymer and having one or more electrical conduction traces disposed on the substrate sheet, wherein the electrical conduction traces may be an electrically conductive material. As represented in FIG. 2, a method for disposal of at least one biodegradable printed circuit board may include removing electronic components from the substrate sheet of the printed circuit board, composting the substrate sheet to degrade the biodegradable polymer into a compost containing the electrically conductive material, and recovering the electrically conductive material from the compost.

For reclamation, as represented in FIG. 2, the electronic components may be sheared of the surface of the substrate, and the substrate may be composted. The biodegradable substrates may be added to a compost pile that may ire dude other organic matter. The compost degradation may be accelerated with natural heat, moisture, and/or pressure. The polymers will decompose to mechanically liberate any inorganic filler and the metal traces. The decomposed blend may be safely smelted to recover the metals without the release of volatile organics. During smelting, any mineral fill will drop off as slag while the metals may liquefy in a melt that can be skimmed off the top.

A method for making a biodegradable printed circuit board may include forming a composite of a first polymer and fiber reinforcements, wherein the first polymer is biodegradable, forming the composite into a substrate sheet, and depositing one or more electrical conduction traces on the substrate sheet. The process of forming the composite into a sheet may include extruding the composite to longitudinally align the fiber reinforcements in the substrate sheet.

In an embodiment, the first polymer may include starch, polyhydroxy alkanoates, polyvinyl alcohol, polylactic acid, poly(3-hydroxypropanoic acid), or any combination thereof. In an embodiment, the fiber reinforcements may include at least one of cellulose, cellulosic fibers, flax, alumina, silicon carbide, aluminum nitride, silicon nitride, silicon dioxide, aluminosilicates, inorganic metal silicate glass fibers, borosilicates, or any combination thereof. In one embodiment, the first polymer may be polylactic acid, and the fiber reinforcements may be inorganic fibers. As mentioned above, the fiber reinforcements may be nano fibers, micro fibers, or both, and may have a cross sectional dimension of about 10 nanometers to about 100 microns and a length of about 100 nanometers to about 1000 microns.

A method for making a biodegradable printed circuit board may also include at least one of: varying the selected fibers, varying a concentration of the selected fibers, and varying a longitudinal orientation of the selected fibers, to alter at least one of elastic modulus, yield stress, ultimate tensile strength, coefficient of thermal expansion, thermal conductivity, impact strength, heat capacity, density, flammability, electrical resistance, dielectric constant, dielectric strength, electric permittivity, magnetic permeability, optical transmissivity, and index of refraction of the composite.

The depositing of the electrical conductive traces may include depositing a conducting paste onto the substrate sheet by at least one of inkjet printing, screen printing, stencil printing, 3D printing, needle dispensing, contact printing, stamp printing, gravure printing, or any combination thereof. The conducting paste may include a biodegradable polymer, a conductive material, and at least one solvent carrier. In one embodiment, the biodegradable polymer may be polylactic acid beads, and the conductive material may be silver. Some examples of solvent may include hexanes, cyclopentanone, propylene glycol butyrolactone, d-limonene, monomethylether acetate (PGMEA). The biodegradable polymer may be in the form of microbeads having a diameter of about 10 nm to about 30 μm.

In an embodiment, the forming of the composite may include forming the composite with the first polymer, the fiber reinforcements, and at least one second polymer to alter at least one of a mechanical property, a thermal property, an electrical property, and an optical property of the composite. The at least one second polymer may be selected from polyolefins, polyesters, polyamides, polyimides, polyketones, polyisocyanates, polysulphones, styrenic plastics, phenolic resins, amide resins, urea resins, melamine resins, polyester resins, epoxidic resins, polycarbonates, polyvinylpyrrolidones, epoxy resins, polyacrylates, rubbers and gums, polyurethanes, silicones, aramids, polybutadiene, polyisoprenes, polyacrylonitriles, polyvinyl difluoride, polyvinyl acetate, polyvinyl alcohol, ethylene vinyl alcohol, vinyl polychloride, polyvinyldiene chloride, biomass derivatives, proteins, polysaccharides, lipids, biopolyesters, or any combination thereof.

In an embodiment, the forming of the composite may include forming the composite with the first polymer, the fiber reinforcements, and at least one additive selected from plasticizers, emulsifiers, anti-flocculants, processing aids, anti statics, light absorbers, antioxidants, cross-linkers, flame retardants, and antibacterials.

In an embodiment, the forming of the composite into a substrate sheet may include forming the composite into a plurality of the substrate sheets, and laminating the plurality of the substrate sheets together. The sheets may be oriented so that the longitudinally aligned reinforcement fibers in at least one substrate sheet are oriented in a direction different from the longitudinally aligned reinforcement fibers in an adjacent substrate sheet. Electrical conduction traces may be formed on each sheet of the plurality of the substrate sheets. The method may further include forming at least one hole in at least one of the substrate sheets at at least one location along the electrical conduction traces, stacking the plurality of substrate sheets to align the at least one hole with one of a hole and an electrical conduction trace in an adjacent substrate sheet, and disposing conductor paste in the at least one hole to electrically connect electrical conduction traces in the adjacent substrate sheets.

A printed circuit board may be configured by placing one or more electronic components on the substrate sheet in contact with the electrical conduction traces. The electronic components may include, but are not limited to at least one of: a microprocessor, a diode, a microcontroller, an integrated circuit, a capacitor, a resistor, a transformer, an inductor, a coil, a logic device, a connector pin, a battery, an antennae, a light emitting diode, a switch, a sensor, and a system-in-package.

### EXAMPLE S

### Example 1

### Flexible Substrate Sheet and Method for Making the Sheet

Flexible substrate sheets will be produced from a composite of polylactic acid and alumina fibers having an average cross sectional dimension of about 50 nanometers and an average length of about 500 nanometers. The sheets will have a thickness of about 200 μm, and will be about 70 wt % polylactic acid and 30 wt % alumina fibers. The longitudinal direction of the alumina fibers will be aligned in a sheet through extrusion of the composite during production of the sheet. For production of the sheets, pellets of polylactic acid will be melted at a temperature of about 155° C., and the alumina fibers will be mixed in. After the mixture is substantially homogenized, the melt will be extruded into a sheet. The temperature of the sheet will be maintained above the softening point at a temperature of about 70° C., and the sheet will be rolled to a thickness of about 200 μm.

### Example 2

### A Single-Layer Biodegradable Printed Circuit Board and Method for Making

A portion of the substrate of Example 1 will be cut into a sheet having a size of about 65 mm by about 125 mm. A mixture of about 60 wt % silver and 40 wt % polylactic acid will be mixed with the solvent gamma butyrolactone to provide a conductor paste, and the paste will be inkjet printed onto the cut substrate sheet in a predetermined pattern. The solvent will be evaporated to leave electrical conduction traces on the substrate for the electrical interconnection of electronic components.

Electronic components, such as, but not limited to, a microprocessor, a diode, a micro-controller, an integrated circuit, a capacitor, a resistor, a transformer, an inductor, a coil, a logic device, a connector pin, a battery, an antennae, a light emitting diode, a switch, a sensor, and a system-in-package, will be mounted on the printed substrate sheet in accordance with a pre-determined pattern using a silver-loaded adhesive.

### Example 3

### A Method for Making a Multi-Layer Printed Circuit Board

A laminate of five layered sheets will be produced for a PCB. Within the laminate, and for references only, sheet 1 will be the top sheet, followed consecutively by sheets 2, 3, 4 and 5, with sheet five as the bottom sheet.

A composite mixture of Example 1 will be extruded and rolled into sheets having a thickness of about 50 μm. Portions of the substrate will be cut into sheets having a size of about 10 cm by about 20 cm, with three sheets (laminate layers 1, 3, and 5) having the longitudinal direction of the fibers running in the longitudinal direction of the sheet, and two sheets (laminate layers 2 and 4) having the longitudinal direction of the fibers running in the width direction of the sheet. With this arrangement, when stacked, each sheet will have fibers oriented approximately perpendicularly to the fibers in an adjacent sheet, and the fibers in every other layer will be approximately parallel.

Holes will be drilled in the upper sheets (layers 1-4) in predetermined locations to provide electrical vias between the layers. A mixture of about 60 wt % silver and 40 wt % polylactic acid will be mixed with the solvent d-limonene to provide a conductor paste. The paste will be inkjet-printed onto each of the five cut substrate sheets in a predetermined pattern that will include filling in the vias. The solvent will be evaporated to leave electrical conduction traces on the sheets. The sheets will be laminated together to form the PCB substrate by heating under slight pressure to join all the layers and fix the conductor traces.

Electronic components, such as microprocessors, microcontrollers, diodes, integrated circuits, capacitors, resistors, transformers, logic devices, coils, connector pins, batteries, antennae, light emitting diodes, switches, sensors and system-in-packages, will be mounted on the laminate sheet in accordance with a pre-determined pattern using a silver-loaded adhesive.

### Example 4

### Disposing of Printed Circuit Boards and Recovering Metals

Printed circuit boards (PCBs) having a substrate of a biodegradable polymer, such as those of Example 3 will be disposed of by composting. After retrieval of the PCBs, any electronic components on the PCBs will be mechanically scraped off of the substrate. The substrate will be comminuted to break the substrate into smaller pieces. The pieces of the substrate will be sprayed with water and placed into contained composting bins to degrade the biodegradable polymer into a compost containing the silver and alumina fibers. The silver will be recovered by smelting the compost to produce a slag containing the alumina and liquefied silver, and the liquefied silver will be separated from the slag.

This disclosure is not limited to the particular systems, devices and methods described, as these may vary. The terminology used in the description is for the purpose of describing the particular versions or embodiments only, and is not intended to limit the scope.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A biodegradable printed circuit board, comprising:
at least one substrate sheet comprising a composite of a first polymer and fiber reinforcements, wherein the first polymer includes a biodegradable polymer selected from a group consisting of starch, polyhydroxy alkanoates, polyvinyl alcohol, poly(3-hydroxypropanoic acid), polylactic acid, a random copolymer of polylactic acid and at least one additional monomer, a block copolymer of polylactic acid and at least one additional monomer, and a graft copolymer of polylactic acid and at least one additional monomer; and
one or more electrical conduction traces disposed on the at least one substrate sheet.

2. The biodegradable printed circuit board of claim 1, wherein the one or more electrical conduction traces comprise polylactic acid beads and silver.

3.-7. (canceled)

8. The biodegradable printed circuit board of claim 1, wherein the at least one additional monomer is selected from glycolic acid, poly(ethylene glycol), poly(ethylene oxide), poly(propylene oxide), (R)-beta-butyrolactone, delta-valerolactone, epsilon-caprolactone, 1,5-dioxepan-2-one, trimethylene carbonate, alkylthiophene, and N-isopropylacrylamide.

9. The biodegradable printed circuit board of claim 1, wherein the first polymer is polylactic acid.

10. The biodegradable printed circuit board of claim 1, wherein the composite further comprises a second polymer selected from polyolefins, polyesters, polyamides, polyimides, polyketones, polyisocyanates, polysulphones, styrenic plastics, phenolic resins, amide resins, urea resins, melamine resins, polyester resins, epoxidic resins, polycarbonates, polyvinylpyrrolidones, epoxy resins, polyacrylates, rubbers, gums, polyurethanes, silicones, aramids, polybutadiene, polyisoprenes, polyacrylonitriles, polyvinyl difluoride, polyvinyl acetate, polyvinyl alcohol, ethylene vinyl alcohol, vinyl polychloride, polyvinyldiene chloride, biomass derivatives, proteins, polysaccharides, lipids, biopolyesters, or any combination thereof.

11. The biodegradable printed circuit board of claim 1, wherein the fiber reinforcements comprise cellulose, cellulosic fibers, flax, alumina, silicon carbide, aluminum nitride, silicon nitride, silicon dioxide, aluminosilicates, inorganic metal silicate glass fibers, borosilicates, or any combination thereof.

12. (canceled)

13. The biodegradable printed circuit board of claim 1, wherein the fiber reinforcements include one or more of a nano fiber and a micro fiber, wherein the fiber reinforcements are present in the composite in an amount of about 1 wt % to about 75 wt % and wherein the fiber reinforcements have a cross sectional dimension of about 10 nanometers to about 100 microns and a length of about 100 nanometers to about 1000 microns.

14. (canceled)

15. The biodegradable printed circuit board of claim 1, wherein the at least one substrate sheet comprises a plurality of laminated substrate sheets, wherein the fiber reinforcements in at least one first substrate sheet are longitudinally oriented in a direction different from a longitudinal orientation of the fiber reinforcements in an adjacent substrate sheet.

16. (canceled)

17. The biodegradable printed circuit board of claim 1, wherein the at least one substrate sheet is flexible.

18. (canceled)

19. The biodegradable printed circuit board of claim 1, wherein the fiber reinforcements include alumina, silicon carbide, aluminum nitride, silicon nitride, silicon dioxide, aluminosilicates, inorganic metal silicate glass fibers, borosilicates, or any combination thereof.

20. The biodegradable printed circuit board of claim 1, wherein the composite further comprises at least one additive selected from plasticizers, emulsifiers, anti-flocculants, processing aids, antistatics, light absorbers, antioxidants, cross-linkers, flame retardants, and antibacterials.

21. (canceled)

22. The biodegradable printed circuit board of claim 1, further comprising one or more electronic components disposed on the at least one substrate sheet and in contact with the one or more electrical conduction traces.

23.-47. (canceled)

48. A method to produce a biodegradable printed circuit board, the method comprising:
forming a composite of a first polymer and fiber reinforcements, wherein the first polymer includes a biodegradable polymer selected from a group consisting of starch, polyhydroxy alkanoates, polyvinyl alcohol, poly(3-hydroxypropanoic acid), polylactic acid, a random copolymer of polylactic acid and at least one additional monomer, a block copolymer of polylactic acid and at least one additional monomer, and a graft copolymer of polylactic acid and at least one additional monomer;
forming the composite into one or more substrate sheets; and
depositing one or more electrical conduction traces on the one or more substrate sheets.

49. The method of claim 48, wherein forming the composite into the one or more substrate sheets includes extruding the composite to longitudinally align the fiber reinforcements in the one or more substrate sheets.

50.-53. (canceled)

54. The method of claim 48, wherein forming the composite of the first polymer and the fiber reinforcements comprises forming the composite of the first polymer and fiber reinforcements with fiber reinforcements comprising cellulose, cellulosic fibers, flax, alumina, silicon carbide, aluminum nitride, silicon nitride, silicon dioxide, aluminosilicates, inorganic metal silicate glass fibers, borosilicates, or any combination thereof.

55.-56. (canceled)

57. The method of claim 48, further comprising varying one or more of the fiber reinforcements, a concentration of the fiber reinforcements, and a longitudinal orientation of the fiber reinforcements to alter at least one of elastic modulus, yield stress, ultimate tensile strength, coefficient of thermal expansion, thermal conductivity, impact strength, heat capacity, density, flammability, electrical resistance, dielectric constant, dielectric strength, electric permittivity, magnetic permeability, optical transmissivity, and index of refraction of the composite.

58.-59. (canceled)

60. The method of claim 48, wherein depositing the one or more electrical conduction traces comprises depositing a conductive paste onto the one or more substrate sheets by inkjet printing, screen printing, stencil printing, 3D printing, needle dispensing, contact printing, stamp printing, gravure printing, or any combination thereof.

61. The method of claim 60, wherein depositing the conductive paste comprises depositing polylactic acid beads, silver, and at least one solvent carrier.

62.-65. (canceled)

66. The method of claim 48, further comprising forming the composite with at least one second polymer to alter at least one of a mechanical property, a thermal property, an electrical property and an optical property of the composite, wherein the at least one second polymer is selected from polyolefins, polyesters, polyamides, polyimides, polyketones, polyisocyanates, polysulphones, styrenic plastics, phenolic resins, amide resins, urea resins, melamine resins, polyester resins, epoxidic resins, polycarbonates, polyvinylpyrrolidones, epoxy resins, polyacrylates, rubbers and gums, polyurethanes, silicones, aramids, polybutadiene, polyisoprenes, polyacrylonitriles, polyvinyl difluoride, polyvinyl acetate, polyvinyl alcohol, ethylene vinyl alcohol, vinyl polychloride, polyvinyldiene chloride, biomass derivatives, proteins, polysaccharides, lipids, biopolyesters, or any combination thereof.

67. The method of claim 48, further comprising forming the composite with at least one additive selected from plasticizers, emulsifiers, anti-flocculants, processing aids, anti statics, light absorbers, antioxidants, cross-linkers, flame retardants, and antibacterials.

68. The method of claim 48, wherein forming the composite into the one or more substrate sheets comprises forming the composite into a substrate sheet having a thickness of about 50 microns to about 3 millimeters.

69. The method of claim 48, wherein:
forming the composite into the one or more substrate sheets comprises forming the composite into a plurality of the substrate sheets; and
the method further comprises laminating the plurality of the substrate sheets.

70. The method of claim 69, further comprising orienting at least one of the plurality of substrate sheets to dispose longitudinally aligned reinforcement fibers in at least one substrate sheet in a direction different from longitudinally aligned reinforcement fibers in an adjacent substrate sheet.

71. The method of claim 70, wherein depositing the one or more electrical conduction traces comprises depositing electrical conduction traces on the plurality of the substrate sheets.

72. The method of claim 71, further comprising:
forming at least one hole in at least one of the substrate sheets at at least one location along the electrical conduction traces;
stacking the plurality of substrate sheets to align the at least one hole with one of a hole and an electrical conduction trace in the adjacent substrate sheet; and
disposing conductor paste in the at least one hole to electrically couple electrical conduction traces in adjacent substrate sheets.

73.-74.(canceled)

75. The method of claim 48, further comprising disposing one or more electronic components on the one or more substrate sheets in contact with the one or more electrical conduction traces, wherein the electronic components comprise at least one of: a microprocessor, a diode, a microcontroller, an integrated circuit, a capacitor, a resistor, a transformer, an inductor, a coil, a logic device, a connector pin, a battery, an antennae, a light emitting diode, a switch, a sensor, and a system-in-package.

76. A method to dispose of at least one biodegradable printed circuit board, the method comprising:
removing electronic components from a substrate sheet of the at least one biodegradable printed circuit board, the substrate sheet comprising:
a biodegradable polymer selected from a group consisting of starch, polyhydroxy alkanoates, polyvinyl alcohol, poly(3-hydroxypropanoic acid), polylactic acid, a random copolymer of polylactic acid and at least one additional monomer, a block copolymer of polylactic acid and at least one additional monomer, and a graft copolymer of polylactic acid and at least one additional monomer; and
one or more electrical conduction traces disposed on the substrate sheet, wherein the one or more electrical conduction traces comprise an electrically conductive material;
composting the substrate sheet to degrade the biodegradable polymer into a compost that contains the electrically conductive material; and
recovering the electrically conductive material from the compost.

77. The method of claim 76, wherein recovering comprises recovering electrically conductive material comprising a metal by:
smelting the compost to produce slag and liquefied metal; and
separating the liquefied metal from the slag.

78. (canceled)

79. The method of claim 76, wherein removing electrical components comprises removing electrical components from a substrate sheet comprising a composite of the biodegradable polymer and fiber reinforcements.

80.-83. (canceled)

84. The method of claim 76, further comprising accelerating the composting by at least one of: heating the substrate sheet, adding moisture to the substrate sheet, and composting the substrate sheet under pressure.
